(19) United States
(12) Patent Application Publication
(10) Pub. No.: US 2016/0118537 A1
(43) Pub. Date: Apr. 28, 2016

(54) SEMICONDUCTOR LIGHT-EMITTING ELEMENT

(71) Applicant: STANLEY ELECTRIC CO., LTD., Tokyo (JP)

(72) Inventors: Mitsuyasu KUMAGAI, Yokohama-shi (JP); Ji-Hao LIANG, Yokohama-shi (JP)

(73) Assignee: STANLEY ELECTRIC CO., LTD., Tokyo (JP)

(21) Appl. No.: 14/878,587

(22) Filed: Oct. 8, 2015

(30) Foreign Application Priority Data
Oct. 23, 2014 (JP) 2014-216233

(51) Int. Cl. H01L 33/14; H01L 33/06; H01L 33/32

(52) U.S. Cl. CPC H01L 33/145; H01L 33/32; H01L 33/06

(57) ABSTRACT

A semiconductor light-emitting element comprises: a first semiconductor layer, an active layer having a multiple quantum well structure in which a plurality of well layers and a plurality of barrier layers are alternately layered, an electron block layer, and a second semiconductor layer. Among the barrier layers, an endmost barrier layer closest to the second semiconductor layer includes a first endmost barrier layer part and a second endmost barrier layer part formed on a side closer to the second semiconductor layer than the first endmost barrier layer part and having a larger band gap than that of the first endmost barrier layer part. The first endmost barrier layer part has a band gap that is larger than that of each of the well layers and is smaller than that of each barrier layer other than the endmost barrier layer.

### BACKGROUND OF THE INVENTION

1. Field of the Invention

The present invention relates to a semiconductor light-emitting element such as a light-emitting diode (LED).

2. Background Art

A semiconductor light-emitting element is generally produced as follows. A semiconductor structure layer including an n-type semiconductor layer, an active layer, and a p-type semiconductor layer is grown on a growth substrate, and an n-electrode and a p-electrode that are used to apply a voltage to the n-type semiconductor layer and the p-type semiconductor layer, respectively, are formed.

Japanese Patent No. 3857295 discloses a semiconductor light-emitting element including an active layer having a plurality of barrier layers and a well layer interposed between the barrier layers, wherein an endmost barrier layer disposed on a side closest to a p-type clad layer among the barrier layers includes a plurality of endmost partial barrier layers. Japanese Patent No. 3857295 further describes that the endmost partial barrier layer on a side closes to the p-type clad layer among the plurality of endmost partial barrier layers has a smaller band gap than that of each barrier layer other than the endmost barrier layer.

Japanese Patent Application Laid-Open No. 2004-87908 discloses a semiconductor light-emitting element including a light-emitting layer having a multiple quantum well structure in which a plurality of well layers and a plurality of barrier layers are layered, wherein the well layers are formed from an InGaN layer, and the barrier layers include an InGaN layer and a GaN layer.

### SUMMARY OF THE INVENTION

A semiconductor light-emitting element emits light by combination (i.e., recombination) of electrons and holes injected from electrodes in an active layer. An increase in the amounts of the injected electrons and holes, that is, the amount of current flowing in the element increases the amounts of electrons and holes to be recombined, to enhance the light-emitting intensity. However, during operation at high temperature, driving at high current, or the like, the light-emitting efficiency, that is, the light-emitting intensity against the level of current applied to the element decreases. Specifically, during operation at high temperature, the amounts of electrons and holes to be recombined (i.e., recombination probability) among the injected electrons and holes decrease.

A decrease in the light-emitting efficiency during the operation at high temperature is caused by hot carriers generated from electrons and holes during the operation at high temperature or the driving at high current. For example, electrons (i.e., hot electrons) as the hot carriers are likely to be injected from an n-type semiconductor layer, cross the active layer (without being combined with holes within the active layer), and move (i.e., overflow) to a p-type semiconductor layer with high probability.

In order to suppress the decrease in light-emitting efficiency during the operation at high temperature or the like, it is preferable that the carriers certainly remain in the active layer and the recombination probability be enhanced.

The present invention has been made in view of the circumstances, and it is an object of the present invention to provide a high-performance semiconductor light-emitting element having a structure that certainly allows electrons to remain in an active layer even during operation at high temperature or driving at high current, and having a high light-emitting efficiency.

A semiconductor light-emitting element according to the present invention includes a first semiconductor layer having a first conductivity type, an active layer formed on the first semiconductor layer and having a multiple quantum well structure in which a plurality of well layers and a plurality of barrier layers are alternately layered, an electron block layer formed on the active layer, and a second semiconductor layer formed on the electron block layer and having a second conductivity type opposite to the first conductivity type. Among the barrier layers, an endmost barrier layer closest to the second semiconductor layer includes a first endmost barrier layer part, and a second endmost barrier layer part formed on a side closer to the second semiconductor layer than the first endmost barrier layer part and having a larger band gap than that of the first endmost barrier layer part. The first endmost barrier layer part has a band gap that is larger than that of each of the well layers and is smaller than that of each barrier layer other than the endmost barrier layer.

### BRIEF DESCRIPTION OF THE DRAWINGS

FIGS. 1A and 1B are cross-sectional views illustrating a configuration of a semiconductor light-emitting element according to a first embodiment;

FIG. 2A is a cross-sectional view illustrating a structure of an active layer in the semiconductor light-emitting element according to the first embodiment;

FIG. 2B is a view illustrating a band diagram of a semiconductor structure layer of the semiconductor light-emitting element according to the first embodiment;

FIG. 3A is a graph illustrating a relationship between an In composition of a first endmost barrier layer part in the semiconductor light-emitting element according to the first embodiment and the light-emitting intensity of the element; and

FIG. 3B is a graph illustrating a relationship between a thickness ratio of the first endmost barrier layer part and a second endmost barrier layer part in an endmost barrier layer and the light-emitting intensity of the element.

### DETAILED DESCRIPTION OF THE INVENTION

Hereinafter, an embodiment of the present invention will be described in detail.

### First Embodiment

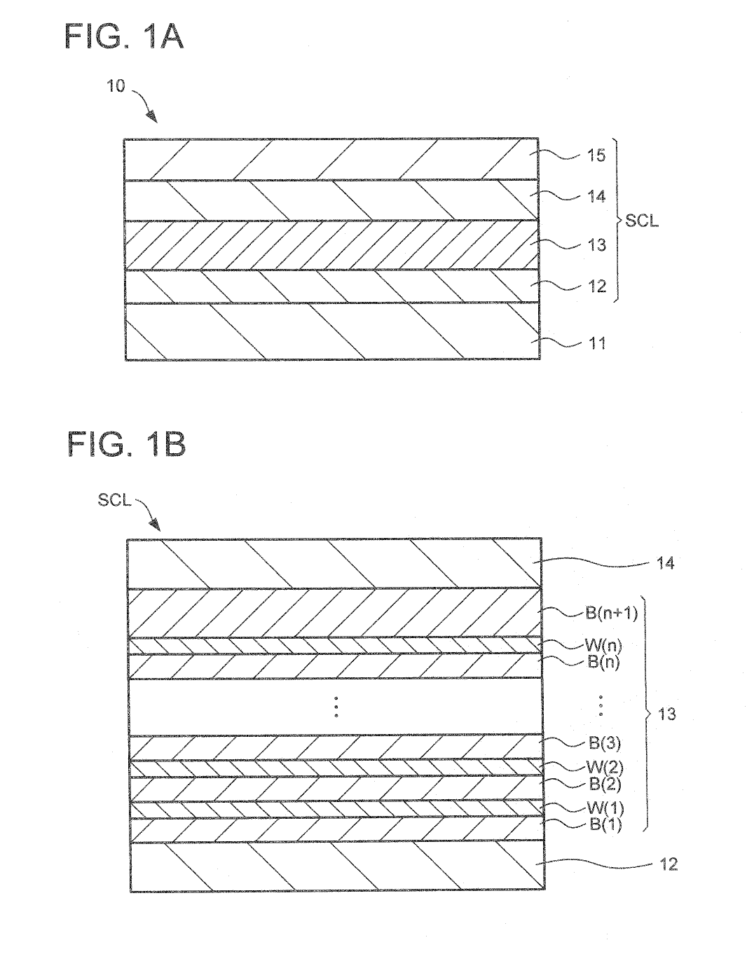

FIG. 1A is a cross-sectional view illustrating a structure of a semiconductor light-emitting element 10 (hereinafter sometimes simply referred to as light-emitting element or element) according to a first embodiment. The semiconductor light-emitting element 10 has a structure in which a semiconductor structure layer SCL is formed on a mounting substrate 11. The semiconductor structure layer SCL includes an n-type semiconductor layer (first semiconductor layer) 12 formed on the mounting substrate 11, an active layer 13 formed on the n-type semiconductor layer 12, an electron block layer 14 formed on the active layer 13, and a p-type semiconductor layer (second semiconductor layer) 15 formed on the electron block layer 14. The p-type semiconductor layer 15 has a conductivity type opposite to the conductivity type of the n-type semiconductor layer 12.

In the present embodiment, the mounting substrate 11 is a growth substrate used for growth of the semiconductor structure layer SCL. For example, the mounting substrate 11 is formed from sapphire. The semiconductor structure layer SCL is formed from a nitride-based semiconductor. The semiconductor light-emitting element 10 can be produced by growing the semiconductor structure layer SCL on a c-plane sapphire substrate, for example, by metal organic chemical vapor deposition (MOCVD)

In this embodiment, a case where the light-emitting element 10 has a structure in which the semiconductor structure layer SCL is formed on the growth substrate as the mounting substrate 11 will be described. However, the present invention is not limited to the case where the mounting substrate 11 is the growth substrate. For example, the semiconductor light-emitting element 10 may have a structure that is obtained by growing the semiconductor structure layer SCL on the growth substrate, bonding the semiconductor structure layer SCL to another substrate, and removing the growth substrate. In this case, the substrate to be bonded is the mounting substrate 11. For the substrate to be bonded, a high-heat dissipation material such as Si, AlN, Mo, W, and CuW can be used.

A buffer layer, not shown, may be provided between the mounting substrate 11 and the n-type semiconductor layer 12. Further, an intermediate layer may be provided between the n-type semiconductor layer 12 and the active layer 13. The buffer layer and the intermediate layer are provided to decrease distortion that may be generated in an interface between the growth substrate and the semiconductor structure layer SCL and an interface of each layer in the semiconductor structure layer SCL. Although not shown in the drawings, the light-emitting element 10 has an n-electrode and a p-electrode that are used to apply a voltage to the n-type semiconductor layer 12 and the p-type semiconductor layer 15, respectively.

FIG. 1B is a cross-sectional view illustrating the structure of the semiconductor structure layer SOL. As shown in FIG. 1B, the active layer 13 has a multiple quantum well (MQW) structure. In the MQW structure, a plurality of (in the embodiment, the number is n) well layers W(1) to W(n) and a plurality of (in the embodiment, the number is n+1) barrier layers B(1) to B(n+1) are alternately layered.

Specifically, the first barrier layer B(1) is layered on the n-type semiconductor layer 12, the first well layer W(1) is layered on the first barrier layer B(1), and the second. barrier layer B(2) is layered on the first well layer W(1). Similarly, each of the well layers W(2) to W(n) and each of the barrier layers B(3) to B(n) are alternately layered on the second barrier layer B(2). On the n-th well layer W(n) that is a well layer closest to the p-type semiconductor layer 15, the (n+1)th barrier layer B(n+1) is formed. The electron block layer 14 is formed on the (n+1)th barrier layer B(n+1).

Specifically, the active layer 13 has a structure in which each of n well layers W(1) to W(n) is provided at each interval between the first barrier layer B(1) that is disposed on a side closest to the n-type semiconductor layer 12 and the (n+1)th barrier layer B(n+1) that is disposed on a side closest to the p-type semiconductor layer 15. In the structure of the active layer 13, n well layers W(1) to W(n) are each formed between adjacent ones among n+1 barrier layers B(1) to B(n+1).

As used herein, the (n+1)th barrier layer B(n+1), which is disposed on a side closest to the p-type semiconductor layer 15, among n+1 barrier layers B(1) to B(n+1), is referred to as an endmost barrier layer.

For example, the n-type semiconductor layer 12 is formed from a GaN layer containing an n-type dopant (for example, Si). The electron block layer 14 is formed from an AlGaN layer. The p-type semiconductor layer 15 is formed from a GaN layer containing a p-type dopant (for example, Mg). The electron block layer 14 may contain the p-type dopant.

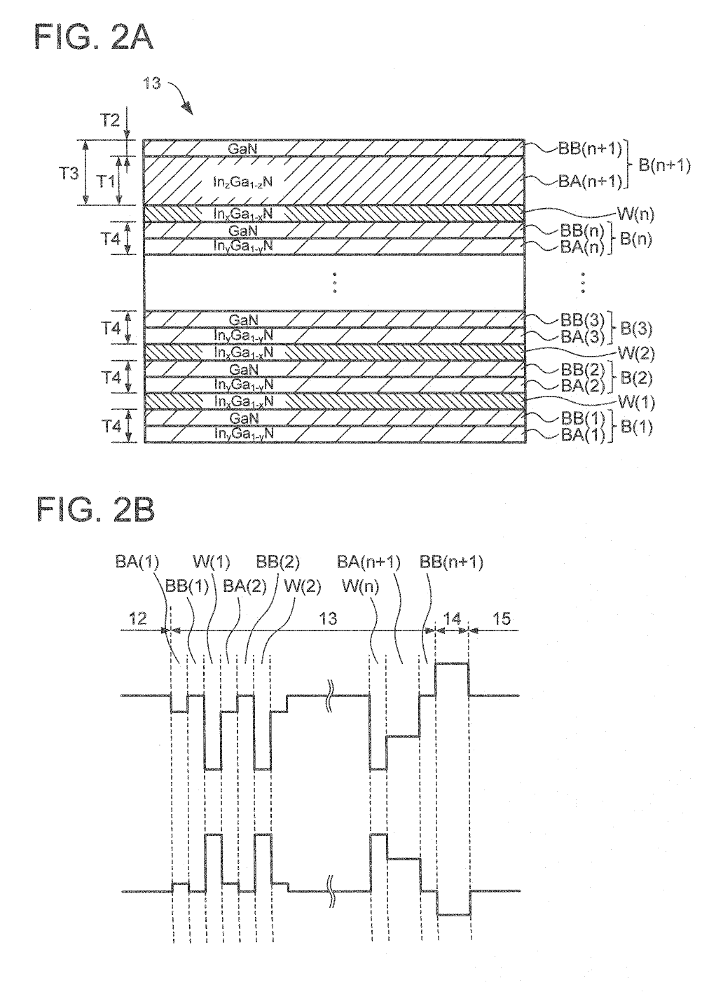

FIG. 2A is a cross-sectional view illustrating the structure of the active layer 13. In the present embodiment, each of the well layers W(1) to W(n) has a composition of InₓGa₁₋ₓN (0<x<1). As shown in FIG. 2A, each of the barrier layers B(1) to B(n+1) has first barrier layer parts BA(1) to BA(n+1) and second barrier layer parts BB(1) to BB(n+1), that is, has a multilayer structure containing the barrier layer parts. In this embodiment, a case where each of the barrier layers B(1) to B(n+1) has a two-layer structure will be described. The second barrier layer parts BB(1) to BB(n+1) are formed on a side closer to the p-type semiconductor layer 15 than the first barrier layer parts BA(1) to BA(n+1).

Each of the first barrier layer parts BA(1) to BA(n+1) is a barrier layer part disposed on a side closest to the n-type semiconductor layer 12 of the barrier layer parts of each of the barrier layers B(1) to B(n+1) Each of the second barrier layer parts BB(1) to BB(n+1) is a barrier layer part disposed on a side closest to the p-type semiconductor layer 15 of the barrier layer parts of each of the barrier layers B(1) to B(n+1). In this embodiment, each of the second barrier layer parts BB(1) to BB(n+1) is formed on corresponding one of the first barrier layer parts BA(1) to BA(n+1).

As used herein, the first barrier layer part BA(n+1) in the endmost barrier layer B(n+1) is referred to as a first endmost barrier layer part, and the second barrier layer part BB(n+1) is referred to as a second endmost barrier layer part. The second endmost barrier layer part BB(n+1) is formed on a side closer to the p-type semiconductor layer 15 than the first endmost barrier layer part BA(n+1).

In this embodiment, among the first barrier layer parts BA(1) to BA(n+1), each of the first barrier layer parts BA(1) to BA(n) in n barrier layers (first to n-th barrier layers) B(1) to B(n) except for the endmost barrier layer B(n+1) has a composition of In_{y}Ga_{1-y}N (0<y<1). Among the first barrier layer parts BA(1) to BA(n+1), the first endmost barrier layer part BA(n+1) in the endmost barrier layer B(n+1) has a composition of In_{z}Ga_{1-z}N (0<z<1). Each of the second barrier layer parts BB(1) to BB(n+1) has a composition of GaN.

The first endmost barrier layer part BA(n+1) in the endmost barrier layer B(n+1) has an In composition z that is smaller than the composition of each of the well layers W(1) to W(n) and is larger than that of each of the first barrier layer parts BA(1) to BA(n) in the other barrier layers B(1) to B(n). Specifically, suppose a case where the In composition of each of the well layers W(1) to W(n) is a composition x, the In composition of each of the first barrier layer parts BA(1) to BA(n) in each of the barrier layers B(1) to B(n) is a composition y, and the In composition of the first endmost barrier layer part BA(n+1) in the endmost barrier layer B(n+1) is a composition z. In this case, the compositions x, y and z satisfy a relationship of y<z<x. As used herein, this composition relationship is referred to as a composition condition.

As shown in FIG. 2A, the first endmost barrier layer part BA(n+1) in the endmost barrier layer B(n+1) has a thickness T1 that is larger than that of the second endmost barrier layer part BB(n+1) in the endmost barrier layer B(n+1). Specifically, the thickness T1 of the first endmost barrier layer part BA(n+1) is larger than the thickness T2 of the second endmost barrier layer part BB(n+1). As used herein, this relationship between the thicknesses of the endmost barrier layer parts in the endmost barrier layer B(n+1) is referred to as a thickness ratio condition.

The first endmost barrier layer part BA(n+1) in the endmost barrier layer B(n+1) has a thickness T1 that is equal to or larger than that of each of the other barrier layers B(1) to B(n). Specifically, the thickness T1 of the first endmost barrier layer part BA(n+1) in the endmost barrier layer B(n+1) is equal to or larger than the thickness T4 of each of the first to n-th barrier layers B(1) to B(n). As used herein, this thickness relationship is referred to as a thickness condition. In this embodiment, the thickness T3 of the endmost barrier layer B(n+1) is a total thickness (T1+T2) of the first endmost barrier layer part BA(n+1) and the second endmost barrier layer part BB(n+1), and is larger than the thickness T4 of each of the other barrier layers B(1) to B(n).

One example of thickness that satisfies the aforementioned thickness ratio condition and thickness condition will be described. In this embodiment, a semiconductor structure layer SCL having the following layer thicknesses was produced. In this embodiment, the well layers W(1) to W(n) each have a thickness of 4 nm. In the barrier layers B(1) to B(n) other than the endmost barrier layer B(n+1), the first barrier layer parts BA(1) to BA(n) each have a thickness of 3 nm. The second barrier layer parts BB(1) to BB(n) each have a thickness of 2 nm. In the endmost barrier layer B(n+1), the first endmost barrier layer part BA(n+1) has a thickness T1 of 5 nm. The second endmost barrier layer part BB(n+1) has a thickness T2 of 2 nm.

In this embodiment, a case where each of the first to n-th barrier layers B(1) to B(n) has the same thickness T4 and the same In composition y will be described. A case where the well layers W(1) to W(n) each have the same In composition x will also be described.

FIG. 2B is a view illustrating a band diagram in the semiconductor structure layer SCL. Each of the second barrier layer parts BB(1) to BB(n+1) in the barrier layers B(1) to B(n+1) has a band gap that is the same as those in the n-type semiconductor layer 12 and the p-type semiconductor layer 15. Each of the first barrier layer parts BA(1) to BA(n) in the barrier layers B(1) to B(n) has the same band gap. Each of the second barrier layer parts BB(1) to BB(n) in the barrier layers B(1) to B(n) has a band gap that is larger than that of each of the first barrier layer parts BA(1) to BA(n).

The second endmost barrier layer part BB(n+1) in the endmost barrier layer B(n+1) has a band gap that is larger than that of the first endmost barrier layer part BA(n+1). The second endmost barrier layer part BB(n+1) has a band gap that is the same as that of each of the barrier layers B(1) to B(n).

The first endmost barrier layer part BA(n+1) in the endmost barrier layer B(n+1) has a band gap that is larger than that of each the well layers W(1) to W(n) and is smaller than that of each of the other barrier layers B(1) to B(n). Specifically, the first endmost barrier layer part BA(n+1) has a band gap that is smaller than that of each of the first barrier layer parts BA(1) to BA(n) in the other barrier layers B(1) to B(n). This is achieved by forming the active layer 13 so as to satisfy the aforementioned composition condition, thickness ration condition, and thickness condition.

When there is a quantum well structure like the active layer 13, a band gap used herein represents an energy between quantum levels in each layer.

Since the first endmost barrier layer part BA(n+1) has a band gap as shown in FIG. 2B, the first endmost barrier layer part BA(n+1) functions as an electron trapping layer in the active layer 13. Specifically, electrons injected from the n-type semiconductor layer 12 remain within the first endmost barrier layer part BA(n+1) with high probability. Therefore, the overflow of electrons beyond the active layer 13 is suppressed. Accordingly, electrons as hot electrons during operation at higher temperature are suppressed from passing through the active layer 13 and reaching the p-type semiconductor layer 15. This makes it possible to suppress a decrease in light-emitting efficiency and maintain the light-emitting efficiency (recombination probability) even during operation at high temperature or low temperature.

The light-emitting element 10 has the electron block layer 14 between the active layer 13 and the p-type semiconductor layer 15. The electron block layer 14 has a band gap that is larger than those of the n-type semiconductor layer 12, the active layer 13, and the p-type semiconductor layer 15. Therefore, the overflow of electrons beyond the active layer 13 to the p-type semiconductor layer 15 side can be suppressed.

In this embodiment, the provision of the endmost barrier layer B(n+1) and the electron block layer 14 synergistically increases an effect of suppressing the electron overflow probability. Specifically, a difference between the band gap of the first endmost barrier layer part BA(n+1) and that of the electron block layer 14 can be increased. Therefore, an electron trapping effect of trapping electrons in the first endmost barrier layer part BA(n+1) and a barrier effect due to the electron block layer 14 are increased. Accordingly, the decrease in light-emitting efficiency during operation at high temperature and during driving at high current is largely suppressed.

The endmost barrier layer B(n+1) has the second endmost barrier layer part BB(n+1) on an interface between endmost barrier layer B(n+1) and the electron block layer 14. The second endmost barrier layer part BB(n+1) has a band gap that is larger than that of the first endmost barrier layer part BA(n+1). The second endmost barrier layer part BB(n+1) has a function of enhancing the crystallinity of the first endmost barrier layer part BA(n+1). Since the difference between the band gap (lattice constant) of the first endmost barrier layer part BA(n+1) and that of the electron block layer 14 is large, the crystallinity on an interface between them is likely to be deteriorated during growth. When the second endmost barrier layer part BB(n+1) is provided, the deterioration of the crystallinity can be suppressed. This also contributes to improvement of the light-emitting efficiency.

In this embodiment, the first endmost barrier layer part BA(n+1) is an InGaN layer, and the electron block layer 14 is an AlGaN layer. In general, it is preferable that the AlGaN layer be grown at a temperature higher than the temperature for InGaN layer by 200° C. or higher. When a GaN layer is not provided as the second endmost barrier layer part BB(n+1) and the AlGaN layer is formed on the InGaN layer, an interface between the AlGaN layer and the InGaN layer is deteriorated due to a difference between the growth temperatures thereof. Specifically, In in the InGaN layer is sublimated during growth of the AlGaN layer. Therefore, the In composition in the formed InGaN layer is not stabilized, and the crystallinity on the interface is also deteriorated.

When a GaN layer is provided as the second endmost barrier layer part BB(n+1), the deterioration of the crystallinity can be suppressed, and the light-emitting efficiency can be improved. When an InGaN layer having relatively large composition is formed as the first endmost barrier layer part BA(n+1) like the embodiment, the provision of GaN (second endmost barrier layer part BB(n+1)) between the InGaN layer and the AlGaN layer as the electron block layer 14 is significantly effective.

When in the barrier layers B(1) to B(n) other than the endmost barrier layer B(n+1), a plurality of barrier layer parts having stepwisely-different band gaps are provided as shown FIGS. 2A and 25, high crystallinity between the well layers and the barrier layers can be maintained. Therefore, a layer having high crystallinity can be formed in the whole active layer 13. Accordingly, it is preferable that each of the barrier layers B(1) to B(n) other than the endmost barrier layer B(n+1) have a multilayer structure.

In this embodiment, a case where the active layer 13 is formed so as to satisfy all the aforementioned composition condition, thickness ratio condition, and thickness condition has been described. However, all the three conditions may not be satisfied as long as the active layer 13 has a band gap shown in FIG. 2B. For example, even when the active layer satisfies the composition condition and the thickness ratio condition, a certain electron trapping effect can be obtained.

A case where each of the barrier layers B(1) to B(n+1) has a two-layer structure has been described. Each of the barrier layers B(1) to B(n+1) may have a structure of three or more layers. For example, the endmost barrier layer B(n+1) may have a third endmost barrier layer part between the first endmost barrier layer part BA(n+1) and the second endmost barrier layer part BB(n+1). Similarly, each of the barrier layers B(1) to B(n) may have third barrier layer parts between the first barrier layer parts BA(1) to BA(n) and the second barrier layer parts BB(1) to BB(n). When the third barrier layer parts including the third endmost barrier layer part are formed, it is preferable that the band gaps thereof be smaller than that of each of the first barrier layer parts BA(1) to BA(n+1) and the second barrier layer parts BB(1) to BB(n+1) and is larger than that of each of the well layers W(1) to W(n).

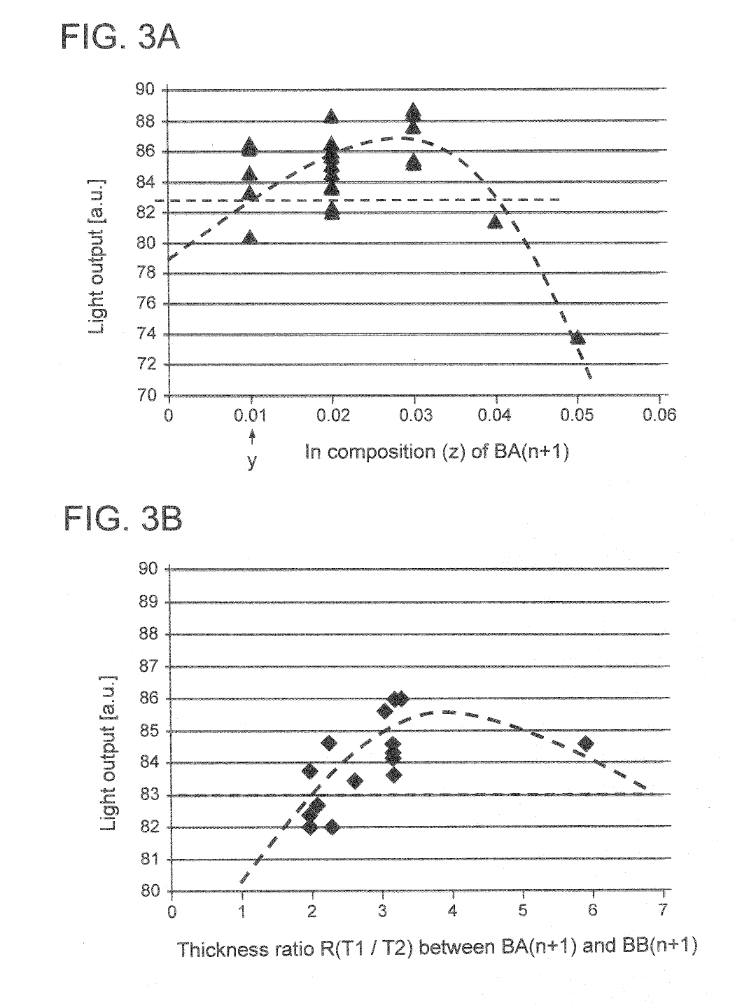

FIG. 3A is a graph illustrating a relationship between the In composition z of the first endmost barrier layer part BA(n+1) in the endmost barrier layer B(n+1) and the light-emitting intensity of the light-emitting element 10. In FIG. 3A, the horizontal axis represents the composition z and the longitudinal axis represents light output. The inventors investigated the relationship between the In composition z of the first endmost barrier layer part BA(n+1) and the light-emitting intensity, and found an optimal range of the composition condition. Specifically, a plurality of light-emitting elements 10 in which the In composition y in the first barrier layer parts BA(1) to BA(n) was fixed to 0.01 and the In composition z in the first endmost barrier layer part BA(n+1) was set to various values were produced. The light-emitting intensities (light output) thereof were measured.

As shown in FIG. 3A, when the composition z satisfies a relationship of 0.02<z<0.04, the light-emitting intensity is high. Specifically, when the composition z is larger than the composition y, the composition y is 0.01, and the composition z satisfies a relationship of 0.02<z<0.04, high light-emitting intensity is shown. When the composition z is larger than 0.04, an influence of distortion due to lattice mismatching excessively increases. Therefore, the light-emitting intensity may decrease. Accordingly, the inventors found a specific upper limit of the composition z.

FIG. 3B is a graph illustrating a relationship between a thickness ratio of the first endmost barrier layer part BA(n+1) and the second endmost barrier layer part BB(n+1) in the endmost barrier layer B(n+1) and the light-emitting intensity of the light-emitting element 10. In FIG. 35, the horizontal axis represents a ratio R of the thickness T1 of the first endmost barrier layer part BA(n+1) to the thickness T2 of the second endmost barrier layer part BB(n+1), and the longitudinal axis represents light output.

The inventors investigated the relationship between the thickness ratio R (T1/T2, see FIG. 2A with respect to the thicknesses T1 and T2) and the light-emitting intensity, and found an optimal range of the thickness ratio condition. Specifically, a plurality of light-emitting elements 10 in which the thickness T2 of the second endmost barrier layer part BB(n+1) was fixed to a certain value and the thickness T1 of the first endmost barrier layer part BA(n+1) was set to various values were produced. The light-emitting intensities (light output) thereof were measured.

As shown in FIG. 3B, when the thickness ratio R (T1/T2) satisfies a relationship of 2<R<7, the light-emitting intensity is high. Specifically, when the thickness T1 is larger than the thickness T2, and the thickness T1 fails within a range of 2 to 7 times the thickness T2, high light-emitting intensity is shown. When the thickness T1 is larger than 7 times the thickness T2, that is, when the thickness of the first endmost barrier layer part BA(n+1) is extremely larger than that of the second endmost barrier layer part BB(n+1), it is conceivable that the crystallinity of the endmost barrier layer B(n+1) is largely deteriorated and the light-emitting intensity decreases.

When the thickness T2 is the same as the thickness T1, that is, when the thickness ratio R is less than 2, the electron trapping effect of the first endmost barrier layer part BA(n+1) decreases. Specifically, suppose a case where the thickness T2 of the second endmost barrier layer part BB(n+1) is increased to the similar size to the thickness T1 of the first endmost barrier layer part BA(n+1). In this case, the band gap of the second endmost barrier layer part BA(n+1) acts to decrease a difference between the band gap of the first endmost barrier layer part BA(n+1) and that of the electron block layer 14 stepwise. Specifically, electrons to be trapped in the first endmost barrier layer part BA(n+1) reach the second endmost barrier layer part BB(n+1) and cross the electron block layer 14 with high probability.

As described, above, the inventors found an optimal range of the thickness ratio R in each layer of the endmost barrier layer B(n+1). Therefore, the inventors have found optimal ranges of the composition condition and thickness ratio condition in addition to the range shown in FIG. 3A,

In this embodiment, the active layer 13 has a multiple quantum well structure. The endmost barrier layer B(n+1) disposed on the side closest to the p-type semiconductor layer 15 has the first endmost barrier layer part BA(n+1) and the second endmost barrier layer part BB(n+1). The first endmost barrier layer part BA(n+1) has a band gap that is larger than that of each of the well layers W(1) to W(n) and is smaller than that of each of the other harrier layers B(1) to B(n). Therefore, the first endmost barrier layer part BA(n+1) functions as an electron trapping layer. Further, electrons remain in the active layer 13 due to the synergistic effect of the function as the electron trapping layer and a barrier function of the electron block layer 14 with high probability. Accordingly, a light-emitting element capable of maintaining high light-emitting efficiency during operation at high temperature and during driving at high current can be provided.

In this embodiment, a case where the first conductivity type is an n-type conductivity type and the second conductivity type is a p-type conductivity type has been described. However, the first conductivity type may be a p-type conductivity type and the second conductivity type may be an n-type conductivity type.

This application is based on a Japanese Patent application No. 2014-216233 which is hereby incorporated by reference.

What is claimed is:

1. A semiconductor light-emitting element comprising:
a first semiconductor layer having a first conductivity type;
an active layer formed on the first semiconductor layer and having a multiple quantum. well structure in which a plurality of well layers and a plurality of barrier layers are alternately layered;
an electron block layer formed on the active layer; and
a second semiconductor layer formed on the electron block layer and having a second conductivity type opposite to the first conductivity type, wherein
among the barrier layers, an endmost barrier layer closest to the second semiconductor layer includes a first endmost barrier layer part, and a second endmost barrier layer part formed on a side closer to the second semiconductor layer than the first endmost barrier layer part and having a larger band gap than that of the first endmost barrier layer part, and
the first endmost barrier layer part has a band gap that is larger than that of each of the well layers and is smaller than that of each barrier layer other than the endmost barrier layer.

2. The semiconductor light-emitting element according to claim 1, wherein
each of the well layers has a composition of InₓGa₁₋ₓN,
each of the other barrier layers has a first barrier layer part having a composition of In_{y}Ga_{1-y}N, and a second barrier layer part disposed on a side closer to the second semiconductor layer than the first barrier layer part and having a larger band gap than. that of the first barrier layer part,
the first endmost barrier layer part has a composition of In_{z}Ga_{1-z}N, and
the composition z satisfies a relationship of y<z<x.

3. The semiconductor light-emitting element according to claim 1, wherein the first endmost barrier layer part has a thickness equal to or larger than that of each of the other barrier layers.

4. The semiconductor light-emitting element according to claim 1, wherein the first endmost barrier layer part has a thickness larger than that of the second endmost barrier layer part.

5. The semiconductor light-emitting element according to claim 4, wherein a thickness ratio R of the thickness of the first endmost barrier layer part to that of the second endmost barrier layer part satisfies a relationship of 2<R<7.

6. The semiconductor light-emitting element according to claim 4, wherein the composition z satisfies a relationship of 0.02<z<0.04.

7. The semiconductor light-emitting element according to claim 1, wherein the second endmost barrier layer part has a composition of GaN and the electron block layer has a composition of AlGaN.
